(19) United States
(12) Patent Application Publication
(10) Pub. No.: US 2024/0085183 A1
(43) Pub. Date: Mar. 14, 2024

(54) AUTONOMOUS NAVIGATION SYSTEM

(71) Applicant: Alps Alpine Co., LTD., Tokyo (JP)

(72) Inventor: Hiroyuki SEINO, Iwaki (JP)

(73) Assignee: Alps Alpine Co., LTD., Tokyo (JP)

(21) Appl. No.: 18/367,045

(22) Filed: Sep. 12, 2023

(30) Foreign Application Priority Data
Sep. 14, 2022 (JP) 2022-146423

(51) Int. Cl. G01C 21/16

(52) U.S. Cl. CPC G01C 21/16

(57) ABSTRACT

A sensor attachment angle detection unit detects a yaw angle A3 of an approximate attachment angle of a six-axis inertial sensor, and a sensor output conversion unit converts acceleration outputs (ax, ay, az) and angular velocity outputs (ωx, ωy, ωz) of three axes Xs, Ys, and Zs in a coordinate system of the six-axis inertial sensor into accelerations (ax′, ay′, az) and angular velocities (ωx′, ωy′, ωz) of three axes Xs′, Ys′, and Zs in the coordinate system having a yaw angle within ±45 according to an angle range to which the detected attachment angle A3 belongs and inputs the converted accelerations and angular velocities to a Kalman filter.

### RELATED APPLICATION

The present application claims priority to Japanese Patent Application Number 2022-146423, filed Sep. 14, 2022, the entirety of which is hereby incorporated by reference.

### BACKGROUND

### 1. Field of the Disclosure

The present disclosure relates to an autonomous navigation system using a Kalman filter.

### 2. Description of the Related Art

An autonomous navigation system mounted on an automobile that utilizes a Kalman filter is known (for example, JP 5164645).

In this autonomous navigation system, an output of a vehicle speed sensor, an output of an acceleration sensor that detects accelerations in three axis directions, an output of a gyroscope that detects angular velocities around three axes, and an output of a GPS receiver are processed through a repeated extended Kalman filter to estimate a state of a three-dimensional position vector or the like of an automobile.

In addition, as a technique related to the present disclosure, a technique for detecting an attachment angle of a device including an acceleration sensor and a gyroscope with respect to an automobile using an output of the acceleration sensor that detects an acceleration in an Xs-axis direction, an output of the gyroscope that detects angular velocity around a Zs-axis perpendicular to the Xs-axis, and an output of a GPS receiver is known (for example, JP 2004-239613 A).

Here, in this technique, assuming that an axis directed in the forward direction of the automobile is Xm and an axis directed in the upward direction of the automobile is Zm, a pitch angle θpitch, a yaw angle θyow, and a roll angle θroll of an Xs-Zs coordinate system with respect to an Xm-Zm coordinate system are obtained as attachment angles with respect to the automobile as follows.

That is, an acceleration As output from the acceleration sensor when an acceleration component in a traveling direction of a vehicle is zero is integrated, and the averaged value Aave is calculated. Then, as represented by Formula 1, the value Aave is divided by the gravitational acceleration g to obtain sin(θpitch), and the pitch angle θpitch is obtained from the value of sin(θpitch).

$$\\ \begin{matrix}[ Math . 1 ] & \\ sin ( θ pitch ) = \frac{Aave}{g} & Formula 1\end{matrix}$$

Next, as represented by Formula 2, g×sin(θpitch) is subtracted from the acceleration As to obtain a value Asx. Then, an acceleration Ar in the X-axis direction of the automobile is obtained on the basis of the output of the GPS receiver, cos(θyaw) is obtained by dividing the value Asx by the cosine value Ar×cos(θpitch) of the acceleration Ar as represented by Formula 3, and the yaw angle θyaw is obtained from the value of cos(θyaw).

$$\\ \begin{matrix}[ Math . 2 ] & \\ Asx = As - g \times sin ( θ pitch ) & Formula 2\end{matrix}$$

$$\\ \begin{matrix}cos ( θ yaw ) = \frac{Asx}{Ar \times cos ( θ pitch )} & Formula 3\end{matrix}$$

In addition, the angular velocity or around the Z axis of the automobile is obtained on the basis of the output of the GPS receiver, and the sensitivity Sg of the gyroscope is obtained by obtaining the ratio of the angular velocity or to the angular velocity ωs output from the gyroscope as represented by Formula 4. Then, as represented by Formula 5, cos(θroll) is obtained by dividing the sensitivity Sg by cos(θpitch), and the roll angle θroll is obtained from the value of cos(θroll).

$$\\ \begin{matrix}[ Math . 3 ] & \\ Sg = \frac{ω s}{ω r} & Formula 4\end{matrix}$$

$$\\ \begin{matrix}cos ( θ roll ) = \frac{Sg}{cos ( θ pitch )} & Formula 5\end{matrix}$$

### SUMMARY

In a case in which an autonomous navigation system is constructed using a six-axis inertial sensor including an acceleration sensor that detects accelerations in three axis directions and a gyroscope that detects angular velocities around three axes, and a Kalman filter, it is also desirable to estimate an attachment angle of the six-axis inertial sensor to the automobile as a state with respect to calculation of a three-dimensional position vector of an automobile.

However, when the attachment angle of the six-axis inertial sensor with respect to the automobile deviates from a standard value of the attachment angle set as an initial value, it takes a long time until the estimated value of the attachment angle converges, or the estimated value of the attachment angle converges to an incorrect value.

In addition, when the yaw angle of the attachment angle of the six-axis inertial sensor with respect to the automobile exceeds ±90°, the attachment angle exceeds an allowable range of the estimation capability of the Kalman filter, and thus the estimated value of the attachment angle may diverge without converging.

This hinders proper calculation of a state of an automobile such as a three-dimensional position vector in an autonomous navigation system using an inertial sensor and a Kalman filter.

Therefore, an objective of the present disclosure is to appropriately calculate a state of a moving body regardless of an attachment angle of an inertial sensor with respect to the moving body in an autonomous navigation system using the inertial sensor and a Kalman filter mounted on the moving body.

To address this objective, one form of an autonomous navigation system mounted on a moving body according to the present disclosure includes: an inertial sensor; a yaw angle detection unit configured to detect a yaw angle of an attachment angle of the inertial sensor with respect to the moving body; a conversion unit configured to convert and output an output of the inertial sensor; and a Kalman filter configured to estimate a state of the moving body using an output of the conversion unit. Here, the state estimated by the Kalman filter includes an attachment angle of the inertial sensor, and the conversion unit converts the output of the inertial sensor into an output of a virtual inertial sensor in which a yaw angle of an attachment angle with respect to the moving body is at least within ±90° according to the yaw angle detected by the yaw angle detection unit, and outputs the converted output.

Furthermore, to address the above objective, another form of an autonomous navigation system mounted on a moving body according to the present disclosure includes: an inertial sensor; a yaw angle angle range detection unit configured to detect, as a yaw angle angle range, an angle range to which a yaw angle of an attachment angle of the inertial sensor with respect to the moving body belongs; a conversion unit configured to convert and output an output of the inertial sensor; and a Kalman filter configured to estimate a state of the moving body using an output of the conversion unit. Here, the state estimated by the Kalman filter includes an attachment angle of the inertial sensor, and the conversion unit converts the output of the inertial sensor into an output of a virtual inertial sensor in which a yaw angle of an attachment angle with respect to the moving body is at least within ±90° according to the yaw angle angle range detected by the yaw angle angle range detection unit, and outputs the converted output.

In some implementations, the yaw angle angle range detection unit detects, as the yaw angle angle range, an angle range to which the yaw angle of the attachment angle of the inertial sensor with respect to the moving body belongs, among an angle range between −45° and +45°, an angle range between +45° and +135°, an angle range between +135° and +180°, an angle range between −45° and −135°, and an angle range between −135° and −180°, and the conversion unit may be configured to convert the output of the inertial sensor into an output of a virtual inertial sensor in which a yaw angle of an attachment angle with respect to the moving body is at least within ±45° according to the yaw angle angle range detected by the yaw angle angle range detection unit and to output the converted output.

Furthermore, in a case of such a configuration, in some implementations, the inertial sensor may be an inertial sensor that outputs accelerations (ax, ay, az) in three orthogonal axial directions of X, Y, and Z, and the conversion unit performs conversion of the accelerations (ax, ay, az) into accelerations (ax′, ay′, az′) as the conversion, and performs conversion into the accelerations (ax′, ay′, az′) by setting (ax′, ay′, az′)=(ax, ay, az) when the yaw angle angle range detected by the yaw angle angle range detection unit is an angle range between −45° and +45°, (ax′, ay′, az′)=(−ay, ax, az) when the yaw angle angle range detected by the yaw angle angle range detection unit is an angle range between +45° and +135°, (ax′, ay′, az′)=(−ax, −ay, az) when the yaw angle angle range detected by the yaw angle angle range detection unit is an angle range between +135° and +180°, (ax′, ay′, az′)=(ay, −ax, az) when the yaw angle angle range detected by the yaw angle angle range detection unit is an angle range between −45° and −135°, and (ax′, ay′, az′)=(−ax, −ay, az) when the yaw angle angle range detected by the yaw angle angle range detection unit is an angle range between −135° and −180°.

Furthermore, in a case of such a configuration, in some implementations, the inertial sensor may be an inertial sensor that outputs angular velocities (ωx, ωy, ωz) around three orthogonal axes of X, Y, and Z, and the conversion unit may perform conversion of the angular velocities (ωx, ωy, ωz) into angular velocities (ωx′, ωy′, ωz′) as the conversion, and perform conversion into the angular velocities (ωx′, ωy′, ωz′) by setting (ωx′, ωy′, ωz′)=(ωx, ωy, ωz) when the yaw angle angle range detected by the yaw angle angle range detection unit is an angle range between −45° and +45°, (ωx′, ωy′, ωz′)=(−ωy, ωx, ωz) when the yaw angle angle range detected by the yaw angle angle range detection unit is an angle range between +45° and +135°, (ωx′, ωy′, ωz′)=(−ωx, −ωy, ωz) when the yaw angle angle range detected by the yaw angle angle range detection unit is an angle range between +135° and +180°, (ωx′, ωy′, ωz′)=(ωy, −ωx, ωz) when the yaw angle angle range detected by the yaw angle angle range detection unit is an angle range between −45° and −135°, and (ωx′, ωy′, ωz′)=(−ωx, −ωy, ωz) when the yaw angle angle range detected by the yaw angle angle range detection unit is an angle range between −135° and −180°.

Furthermore, in a case of such a configuration, in some implementations, the inertial sensor may be an inertial sensor that outputs accelerations (ax, ay, az) and angular velocities (ωx, ωy, ωz), and the conversion unit may perform, as the conversion, conversion of the accelerations (ax, ay, az) into accelerations (ax′, ay′, az′) and conversion of the angular velocities (ωx, ωy, ωz) into angular velocities (ωx′, ωy′, ωz′).

As described above, in the Kalman filter, the output of the inertial sensor is converted by the conversion unit to generate the output of the virtual inertial sensor in which the yaw angle of the attachment angle is within ±90° or +45°, and the output is input to the Kalman filter instead of the output of the inertial sensor, whereby divergence of estimation of the attachment angle can be curbed in the Kalman filter regardless of the attachment angle of the inertial sensor with respect to the moving body, and it can be expected that estimation of the attachment angle can rapidly converge to a correct value.

Here, in implementations of an autonomous navigation system including the above-described yaw angle angle range detection unit, the yaw angle angle range detection unit may be configured to detect the yaw angle of the attachment angle of the inertial sensor with respect to the moving body, and the autonomous navigation system may include an initial value setting unit configured to calculate a yaw angle of the virtual inertial sensor on the basis of the yaw angle and the yaw angle range detected by the yaw angle angle range detection unit and to set the yaw angle in the Kalman filter as an initial value of a yaw angle of an attachment angle estimated by the Kalman filter.

Furthermore, in this case, the yaw angle angle range detection unit may further detect a roll angle and a pitch angle of the attachment angle of the inertial sensor with respect to the moving body, and the initial value setting unit may calculate a pitch angle of the virtual inertial sensor on the basis of the roll angle, the pitch angle, and the yaw angle angle range detected by the yaw angle angle range detection unit, and set the pitch angle in the Kalman filter as an initial value of a pitch angle of an attachment angle estimated by the Kalman filter.

Furthermore, in the autonomous navigation system that detects a yaw angle angle range from among an angle range between −45° and +45°, an angle range between +45° and +135°, an angle range between +135° and +180°, an angle range between −45° and −135°, and an angle range between −135° and −180° through a yaw angle angle range detection unit, the yaw angle angle range detection unit may be configured to detect a roll angle A1, a pitch angle A2, and a yaw angle A3 of the attachment angle of the inertial sensor with respect to the moving body, and the autonomous navigation system may include an initial value setting unit that sets an initial value SA2 of the pitch angle and an initial value SA3 of the yaw angle of the attachment angle estimated by the Kalman filter. In this case, the initial value setting unit calculates the initial value SA2 and the initial value SA3 of the yaw angle as SA2=A2 and SA3=A3 when the yaw angle angle range detected by the yaw angle angle range detection unit is an angle range between −45° and +45°, SA2=A1 and SA3=A3−90° when the yaw angle angle range detected by the yaw angle angle range detection unit is an angle range between +45° and +135°, SA2=−A2 and SA3=A3−180° when the yaw angle angle range detected by the yaw angle angle range detection unit is an angle range between +135° and +180°, SA2=−A1 and SA3=A3+90° when the yaw angle angle range detected by the yaw angle angle range detection unit is an angle range between −45° and −135°, and SA2=−A2 and SA3=A3+180° when the yaw angle angle range detected by the yaw angle angle range detection unit is an angle range between −135° and −180°.

As described above, by setting the initial value of the attachment angle estimated by the Kalman filter, it can be expected that estimation of the attachment angle of the six-axis inertial sensor rapidly converges without diverging.

As described above, in forms an autonomous navigation system according to the present disclosure using an inertial sensor and a Kalman filter mounted on a moving body, a state of the moving body can be appropriately calculated regardless of an attachment angle of the inertial sensor with respect to the moving body.

### BRIEF DESCRIPTION OF THE DRAWINGS

FIG. 1 is a block diagram illustrating a configuration of an autonomous navigation system according to one form of the present disclosure;

FIGS. 2A and 2B are diagrams illustrating yaw angles of an attachment angle of a six-axis inertial sensor with respect to an automobile, estimated by a Kalman filter in one form embodiment of the present disclosure; and

FIGS. 3A to 3E are diagrams illustrating examples of transformation from a coordinate system of a six-axis inertial sensor to a coordinate system of a virtual six-axis inertial sensor in one form of the present disclosure.

### DETAILED DESCRIPTION

Hereinafter, embodiments and implementations of the present disclosure will be described.

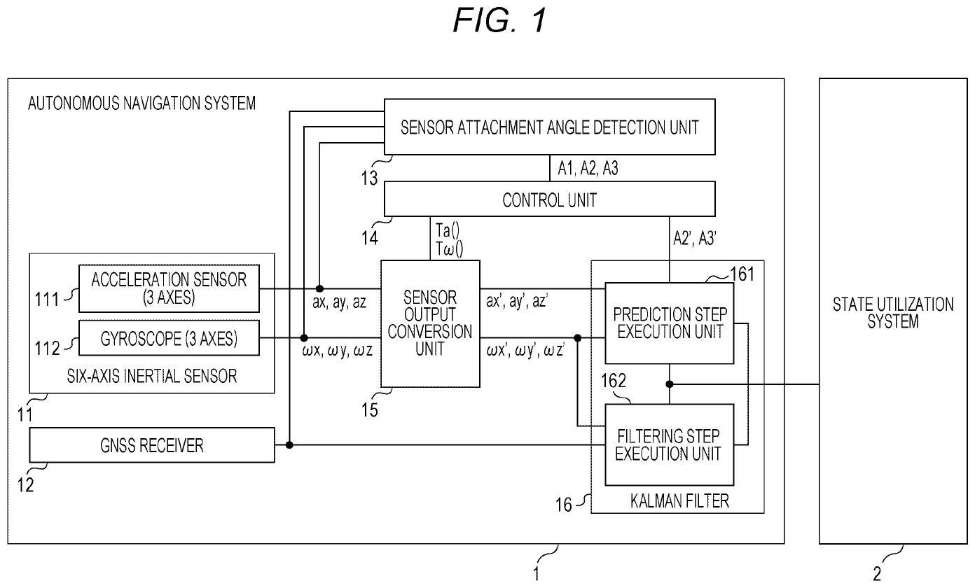

FIG. 1 illustrates a configuration of an autonomous navigation system according to one form of the present disclosure.

The autonomous navigation system 1 is a system that is mounted on an automobile and calculates a state of the automobile such as a position vector of the automobile, where the state of the automobile such as the position vector of the automobile calculated by the autonomous navigation system 1 is used by a state utilization system 2 that is an autonomous driving system, a navigation system, or the like also mounted on the automobile.

As illustrated, the autonomous navigation system 1 may include a six-axis inertial sensor 11, a GNSS receiver 12 that performs satellite positioning, a sensor attachment angle detection unit 13, a control unit 14, a sensor output conversion unit 15, and a Kalman filter 16. In some implementations, the sensor attachment angle detection unit 13, the control unit 14, and/or the sensor output conversion unit may include processor, a central processing unit, or other processing circuitry.

Further, the six-axis inertial sensor 11 includes an acceleration sensor 111 that detects accelerations ax, ay, and az in three-axis directions of Xs, Ys, and Zs in a sensor coordinate system that is an orthogonal coordinate system fixed with respect to the six-axis inertial sensor 11, and a gyroscope 112 that detects angular velocities ωx, ωy, and ωz around three axes Xs, Ys, and Zs.

Further, the Kalman filter 16 includes a prediction step execution unit 161 and a filtering step execution unit 162.

The sensor output conversion unit 15 converts the accelerations ax, ay, and az output from the acceleration sensor 111 into accelerations ax′, ay′, and az′ according to an acceleration conversion function Ta set by the control unit 14, outputs the converted accelerations to the Kalman filter 16, converts the angular velocities ωx, ωy, and ωz output from the gyroscope 112 into angular velocities ωx′, ωy′, and ωz′ according to an angular velocity conversion function Tω set by the control unit 14, and outputs the converted angular velocities to the Kalman filter 16.

Next, the Kalman filter 16 estimates a state Xk of the automobile at each point in time k according to a state equation represented by Formula 6 and an observation equation represented by Formula 7.

[Math. 4]

Xₖ=f(Xₖ₋₁,uₖ)+qₖ Formula 6

zₖ=h(xₖ)+rₖ Formula 7

The estimated state Xk of the automobile includes a three-dimensional position vector (three-dimensional movement distance) of the automobile, a three-dimensional velocity vector of the six-axis inertial sensor 11, attitude angles of roll, pitch, and yaw of the six-axis inertial sensor 11, a pitch angle and a yaw angle of an attachment angle of the six-axis inertial sensor 11 with respect to the automobile, sensitivities and biases of the acceleration sensor 111 and the gyroscope 112, and the like.

In Formula 6, uk represents an input vector including accelerations ax′, ay′, and az′ and angular velocities ωx′, ωy′, and ωz′ input from the sensor output conversion unit 15, and qk represents an error of the input vector. Further, f is a nonlinear function for deriving the state Xk from a state Xk−1 at the previous point in time k−1 and the input vector uk in a case in which there is no error qk.

In Formula 7, Zk represents a measured value of the GNSS receiver input to the Kalman filter 16 via a signal processing unit or a measured value including angular velocities ωx′, ωy′, and ωz′ or the like input from the sensor output conversion unit 15, and rk represents an error of the measured value. Further, h is a nonlinear function for deriving the measured value Zk from the state Xk in a case in which there is no error rk.

The prediction step execution unit 161 and the filtering step execution unit 162 of the Kalman filter 16 perform, for example, the following processing.

That is, the prediction step execution unit 161 of the Kalman filter 16 calculates a prior estimated value X−k+1 of a state Xk+1 according to Formula 8 at the point in time k. Here, X+k in Formula 8 is a posterior estimated value calculated by the filtering step execution unit 162 at the previous point in time k.

$$\\ \begin{matrix}[ Math . 5 ] & \\ {x}_{k + 1}^{-} = \{ \begin{matrix}f ( {x}_{k}^{-} , {u}_{k} ) & ( \begin{matrix}When a measured value is not obtained in a previous point \\ in time k and a posterior estimated value is not calculated\end{matrix} ) \\ f ( {x}_{k}^{+} , {u}_{k} ) & ( \begin{matrix}When a measured value is obtained in a previous point in \\ time k and a posterior estimated value is calculated\end{matrix} )\end{matrix} & Formula 8\end{matrix}$$

In addition, the prediction step execution unit 161 calculates a prior error covariance P-k+1 according to Formula 9. In Formula 9, Φk and Γk are matrices defined by Jacobian of the nonlinear function f, ΦTk and ΓTk are transposed matrices of Φk and Γk, P+k is a posterior error covariance calculated by the filtering step execution unit 162 at the previous point in time k, and Qk is a covariance matrix representing the error qk.

$$\\ \begin{matrix}[ Math . 6 ] & \\ {P}_{k + 1}^{-} = \{ \begin{matrix}{Φ}_{k} {P}_{k}^{-} {Φ}_{k}^{T} + {Γ}_{k} {Q}_{k} {Γ}_{k}^{T} & ( \begin{matrix}When a measured value is not obtained in a previous point \\ in time k and a posterior estimated value is not calculated\end{matrix} ) \\ {Φ}_{k} {P}_{k}^{+} {Φ}_{k}^{T} + {Γ}_{k} {Q}_{k} {Γ}_{k}^{T} & ( \begin{matrix}When a measured value is obtained in a previous point in \\ time k and a posterior estimated value is calculated\end{matrix} )\end{matrix} & Formula 9\end{matrix}$$

Next, in a case in which a measured value is obtained at the point in time k, the filtering step execution unit 162 executes a filtering step that is repeated a predetermined number of times such as once or a plurality of times or until a predetermined stop condition is satisfied while advancing i from 0 by 1 in Formulas 10, 11, and 12.

[Math. 7]

K_{k,i}=Pₖ^{\hat{ }}Hₖ^{T}(x_{k,i}⁺)(Hₖ(x_{k,i}⁺)Pₖ^{˜}Hₖ^{T}(x_{k,i}⁺)+Rₖ)⁻¹ Formula 10

x_{k,i+1}⁺=xₖ⁻+K_{k,i}[zₖ−hₖ(x_{k,i}⁺)−Hₖ(x_{k,i}⁺)(xₖ⁻−x_{k,k}⁺)] Formula 11

P_{k,i+1}⁺=(I−K_{k,i}Hₖ(\hat{x}_{k,i}⁺))Pₖ⁻ Formula 12

Formula 10 is a calculation formula of a Kalman gain Kk,i, P−k in the formula is a prior error covariance calculated in a prediction step at the previous point in time k−1. In addition, x+k,0 is a prior estimated value x−k calculated in the prediction step at the previous point in time k−1.

In addition, Hk is a matrix defined by Jacobian of the nonlinear function h, HTk is a transposed matrix of Hk, and Rk is a covariance matrix representing an error rk.

Next, Formula 11 is a formula for calculating a posterior estimated value X+k,i+1, Formula 12 is a formula for calculating a posterior error covariance P+k,i+1, and I in the formula is an identity matrix.

Then, if iteration of Formulas 10, 11, and 12 is stopped n times, the filtering step execution unit 162 sets a posterior estimated value X+k,n and a posterior error covariance P+k,n finally obtained as the posterior estimated value X+k and the posterior error covariance P+k.

Then, the posterior estimated value X+k is output to the state utilization system 2 as an estimated value of the state Xk+1 of the automobile together with the posterior error covariance P+k,n as necessary.

Note that, in a case in which a measured value cannot be obtained at the point in time k and the filtering step cannot be executed, the prior estimated value X−k is output to the state utilization system 2 together with the posterior error covariance P−k,n as an estimated value of the state Xk of the automobile as necessary.

Such processing of the prediction step execution unit 161 of the Kalman filter 16 is started from a point in time k=1 after the initial value X−0 of the prior estimated value X−k and the initial value P−0 of the prior error covariance P−k are set.

In addition, processing of the filtering step execution unit 162 is started from the point in time k=1 at which the prediction step execution unit 161 calculates the first prior estimated value x−1 and the prior error covariance P−1.

An initial value SA2 of the pitch angle and an initial value SA3 of the yaw angle of the attachment angle of the six-axis inertial sensor 11 with respect to the automobile included in the initial value X−0 of the prior estimated value X−k are set by the control unit 14. As other initial values, an expected value or the like is set.

Hereinafter, setting of the acceleration conversion function Ta and the angular velocity conversion function Tω to the sensor output conversion unit 15 described above and setting of the initial value SA2 of the pitch angle and the initial value SA3 of the yaw angle of the attachment angle of the six-axis inertial sensor 11 as a part of the initial value X−0 of the prior estimated value X−k to the Kalman filter 16, which are performed by the control unit 14, will be described.

First, setting of the acceleration conversion function Ta and the angular velocity conversion function Tw will be described.

The sensor attachment angle detection unit 13 detects an approximate attachment angle (roll angle A1, pitch angle A2, and yaw angle A3) of the six-axis inertial sensor 11 with respect to the automobile at the time of initial setting of the autonomous navigation system 1.

Here, a vehicle coordinate system, which is an orthogonal coordinate system fixed with respect to the automobile, is defined in advance, and three axes of the vehicle coordinate system are an Xm axis directed in the forward direction of the automobile, a Ym axis directed in the right direction of the automobile, and a Zm axis directed in the upward direction of the automobile.

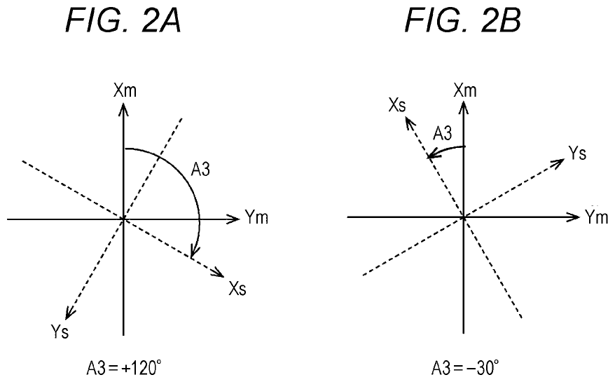

The roll angle A1 of the attachment angle of the six-axis inertial sensor 11 with respect to the automobile is an inclination of the sensor coordinate system around the Xm axis with respect to the vehicle coordinate system, the pitch angle A2 is an inclination of the sensor coordinate system around the Ym axis with respect to the vehicle coordinate system, and the yaw angle A3 is an inclination of the sensor coordinate system around the Zm axis with respect to the vehicle coordinate system as illustrated in FIGS. 2A and 2B. In FIGS. 2A and 2B, the clockwise direction of the yaw angle A3 is defined as the positive direction.

Such detection of an approximate attachment angle (roll angle A1, pitch angle A2, and yaw angle A3) of the six-axis inertial sensor 11 with respect to the automobile, performed by the sensor attachment angle detection unit 13, can be estimated by Formula 1 to Formula 5 based on the output of the acceleration sensor 111, the output of the gyroscope 112, and the output of the GNSS receiver 12 by applying the technology of Patent Literature 2 described above, for example.

However, detection of the approximate attachment angle (roll angle A1, pitch angle A2, and yaw angle A3) of the six-axis inertial sensor 11 with respect to the automobile, performed by of the sensor attachment angle detection unit 13, may be performed by another method, or a roll angle A1, a pitch angle A2, and a yaw angle A3 set by an operator may be estimated as the roll angle A1, the pitch angle A2, and the yaw angle A3 as they are.

In any case, the estimation accuracy of the roll angle A1, the pitch angle A2, and the yaw angle A3 is set to at least the accuracy with which it can be determined whether each angle belongs to any of −45° to +45°, +45° to +135°, −45° to −135°, and +135° to +180°, and −135° to −180°.

Next, according to the angle range to which the yaw angle A3 detected by the sensor attachment angle detection unit 13 belongs, the control unit 14 sets the acceleration conversion function Ta for converting the accelerations ax, ay, and az output from the acceleration sensor 111 into the accelerations ax′, ay′, and az′ in the sensor output conversion unit 15, and the angular velocity conversion function Tω for converting the angular velocities ωx, ωy, and ωz output from the gyroscope 112 into the angular velocities ωx′, ωy′, and ωz′ in the sensor output conversion unit 15 as follows.

When −45°<A3<+45°,

(ax′,ay′,az′)=Ta(ax,ay,az)=(ax,ay,az)

(ωx′,ωy′,ωz′)=Tω(ωx,ωy,ωz)=(ωx,ωy,ωz)
when +45°≤A3<+135°,

(ax′,ay′,az′)=Ta(ax,ay,az)=(−ay,ax,az)

(ωx′,ωy′,ωz′)=Tω(ωx,ωy,ωz)=(−ωy,ωx,ωz)
when +135°≤A3<+180°,

(ax′,ay′,az′)=Ta(ax,ay,az)=(−ax,−ay,az)

(ωx′,ωy′,ωz′)=Tω(ωx,ωy,ωz)=(−ωx,−ωy,ωz)
when −45°≥A3>−135°,

(ax′,ay′,az′)=Ta(ax,ay,az)=(ay,−ax,az)

(ωx′,ωy′,ωz′)=Tω(ωx,ωy,ωz)=(ωy,−ωx,ωz)
when −135°≥A3≥−180°,

(ax′,ay′,az′)=Ta(ax,ay,az)=(−ax,−ay,az)

(ωx′,ωy′,ωz′)=Tω(ωx,ωy,ωz)=(−ωx,−ωy,ωz)

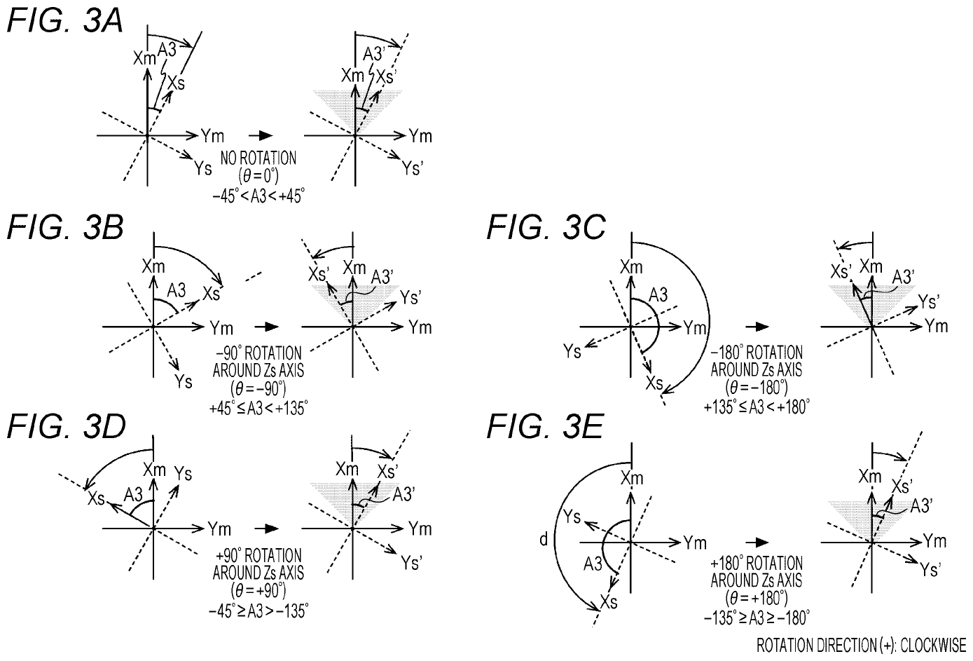

By setting the acceleration conversion function Ta and the angular velocity conversion function Tω in this manner, the accelerations ax, ay, and az output from the acceleration sensor 111 are converted into the acceleration ax′ in the Xs′ axis direction and ay′ representing the acceleration in the Ys′ axis direction shown in FIGS. 3A to 3E for each angle range to which the yaw angle A3 belongs, and az′ representing the acceleration in the Zs axis direction, and the angular velocities ωx, ωy, and ωz output from the gyroscope 112 are converted into ωx′ representing the angular velocity around the Xs′ axis, ωy′ representing the angular velocity around the Ys′ axis, and ωz′ representing the angular velocity around the Zs axis.

That is, the output of the six-axis inertial sensor 11 is converted into the output of a virtual six-axis inertial sensor having a virtual sensor coordinate system in which the Xs′ axis, the Ys′ axis, and the Zs axis are orthogonal three axes.

In addition, since the Xs′ axis and the ys′ axis are obtained by rotating the Xs axis and the ys axis as follows according to the angle range to which the yaw angle A3 belongs in the yaw direction, as illustrated,
0° when −45°<A3<+45°,
−90° when +45°≤A3<+135°,
−180° when +135°≤A3<+180°,
+90° when −45°≥A3>−135°, and
+180° when −135°≥A3≥−180°,
A3′=A3 when −45°<A3<+45°,
A3′=A3−90° when +45°≤A3<+135°,
A3′=A3−180° when +135°≤A3<+180°,
A3′=A3+90° when −45°≥A3>−135°, and
A3′=A3+180° when −135°≥A3≥−180°
   a yaw angle A3′ of an attachment angle of the virtual six-axis inertial sensor with respect to the automobile is as described above, and thus the yaw angle A3′ falls within the range of ±45° indicated in gray in the figure regardless of the yaw angle A3.

Therefore, in the Kalman filter 16, using the output of the virtual six-axis inertial sensor generated according to conversion of the sensor output conversion unit 15 instead of the output of the six-axis inertial sensor 11 is equivalent to using the output of the six-axis inertial sensor in which the yaw angle of the attachment angle with respect to the automobile is A3″ within the range of 45°.

Therefore, it can be expected that estimation of the attachment angle is prevented from diverging regardless of the attachment angle of the six-axis inertial sensor 11 with respect to the automobile, and estimation of the attachment angle can rapidly converge to a correct value.

Next, setting of the initial value SA2 of the pitch angle and the initial value SA3 of the yaw angle of the attachment angle of the six-axis inertial sensor 11, performed by the control unit 14, will be described.

Here, the Kalman filter 16 estimates the pitch angle and the yaw angle of the attachment angle with respect to the vehicle coordinate system that is the virtual six-axis inertial sensor coordinate system in which the Xs′ axis, the Ys′ axis, and the Zs' axis are orthogonal three axes, obtained by rotating the coordinate system of the six-axis inertial sensor 11 in which the Xs axis, the Ys axis, and the Zs axis are orthogonal three axes around the Zs axis by an angle θ determined according to the angle range to which the yaw angle A3 detected by the sensor attachment angle detection unit 13 belongs.

Therefore, the control unit 14 sets the initial value SA2 of the pitch angle and the initial value SA3 of the yaw angle of the attachment angle to the Kalman filter 16 as follows according to the pitch angle A2 and the yaw angle A3 detected by the sensor attachment angle detection unit 13 and the angle range to which the yaw angle A3 belongs.
That is,
SA2=A2, θ=0°, and SA3=A3+θ when −45°<A3<+45°,
SA2=A2, θ=−180°, and SA3=A3+θ when +135°≤A3<+180°, and
SA2=A2, θ=+180°, and SA3=A3+θ when −135°≥A3≥−180°.

Further, in a case in which the angle range to which the yaw angle A3 detected by the sensor attachment angle detection unit 13 belongs is in the following range and it can be expected that the Zs axis of the sensor coordinate system approximates the Zm axis of the vehicle coordinate system, the initial value SA2 of the pitch angle and the initial value SA3 of the yaw angle of the attachment angle are set as follows according to the roll angle A1 and the yaw angle A3 detected by the sensor attachment angle detection unit 13 and the angle range to which the yaw angle A3 belongs.
SA2=A1, θ=−90°, and SA3=A3+θ when +45°≤A3<+135°
SA2=−A1, θ=+90°, and SA3=A3+θ when −45°≥A3≥−135°

By setting the initial value SA2 of the pitch angle and the initial value SA3 of the yaw angle of the attachment angle as described above in the control unit 14, it can be expected that estimation of the pitch angle and the yaw angle of the attachment angle of the six-axis inertial sensor 11 rapidly converges without diverging.

Although the yaw angle A3′ of the virtual six-axis inertial sensor falls within the range of ±45° in the above embodiment, the range in which the yaw angle A3′ falls is not necessarily the range of ±45°, and may be any range of less than ±90°.

The above embodiments and implementations have been described as examples of the present disclosure. It should not be interpreted that the above embodiments and implementations limit the technical range of the present disclosure. That is, the present disclosure can be practiced in various other forms without departing from the spirit and main features of the present disclosure.

1. An autonomous navigation system mounted on a moving body, the autonomous navigation system comprising:
an inertial sensor;
a yaw angle detection unit configured to detect a yaw angle of an attachment angle of the inertial sensor with respect to the moving body;
a conversion unit configured to convert and to output an output of the inertial sensor; and
a Kalman filter configured to estimate a state of the moving body based on an output of the conversion unit;
wherein the state estimated by the Kalman filter includes an attachment angle of the inertial sensor; and
wherein the conversion unit is configured to convert the output of the inertial sensor into an output of a virtual inertial sensor in which a yaw angle of an attachment angle with respect to the moving body is at least within ±90° according to the yaw angle detected by the yaw angle detection unit, and to output the converted output.

2. An autonomous navigation system mounted on a moving body, the autonomous navigation system comprising:
an inertial sensor;
a yaw angle angle range detection unit configured to detect, as a yaw angle angle range, an angle range to which a yaw angle of an attachment angle of the inertial sensor with respect to the moving body belongs;
a conversion unit configured to convert and to output an output of the inertial sensor; and
a Kalman filter configured to estimate a state of the moving body using an output of the conversion unit;
wherein the state estimated by the Kalman filter includes an attachment angle of the inertial sensor; and
wherein the conversion unit is configured to convert the output of the inertial sensor into an output of a virtual inertial sensor in which a yaw angle of an attachment angle with respect to the moving body is at least within ±90° according to the yaw angle angle range detected by the yaw angle angle range detection unit, and to output the converted output.

3. The autonomous navigation system according to claim 2, wherein:
the yaw angle angle range detection unit is configured to detect, as the yaw angle angle range, an angle range to which the yaw angle of the attachment angle of the inertial sensor with respect to the moving body belongs, among an angle range between −45° and +45°, an angle range between +45° and +135°, an angle range between +135° and +180°, an angle range between −45° and −135°, and an angle range between −135° and −180°; and
the conversion unit is configured to convert the output of the inertial sensor into an output of a virtual inertial sensor in which a yaw angle of an attachment angle with respect to the moving body is at least within ±45° according to the yaw angle angle range detected by the yaw angle angle range detection unit, and to output the converted output.

4. The autonomous navigation system according to claim 3, wherein:
the inertial sensor is an inertial sensor that is configured to output accelerations (ax, ay, az) in three orthogonal axial directions of X, Y, and Z; and
the conversion unit is configured to perform conversion of the accelerations (ax, ay, az) into accelerations (ax′, ay′, az′) as the conversion, and to perform conversion into the accelerations (ax′, ay′, az′) by setting:
(ax′, ay′, az′)=(ax, ay, az) when the yaw angle angle range detected by the yaw angle angle range detection unit is an angle range between −45° and +45°;
(ax′, ay′, az′)=(−ay, ax, az) when the yaw angle angle range detected by the yaw angle angle range detection unit is an angle range between +45° and +135°;
(ax′, ay′, az′)=(−ax, −ay, az) when the yaw angle angle range detected by the yaw angle angle range detection unit is an angle range between +135° and +180°;
(ax′, ay′, az′)=(ay, −ax, az) when the yaw angle angle range detected by the yaw angle angle range detection unit is an angle range between −45° and −135°; and
(ax′, ay′, az′)=(−ax, −ay, az) when the yaw angle angle range detected by the yaw angle angle range detection unit is an angle range between −135° and −180°.

5. The autonomous navigation system according to claim 3, wherein:
the inertial sensor is an inertial sensor that is configured to output angular velocities (ωx, ωy, ωz) around three orthogonal axes of X, Y, and Z; and
the conversion unit is configured to perform conversion of the angular velocities (ωx, ωy, ωz) into angular velocities (ωx′, ωy′, ωz′) as the conversion, and to perform conversion into the angular velocities (ωx′, ωy′, ωz′) by setting:
(ωx′, ωy′, ωz′)=(ωx, ωy, ωz) when the yaw angle angle range detected by the yaw angle angle range detection unit is an angle range between −45° and +45°;
(ωx′, ωy′, ωz′)=(−ωy, ωx, ωz) when the yaw angle angle range detected by the yaw angle angle range detection unit is an angle range between +45° and +135°;
(ωx′, ωy′, ωz′)=(−ωx, −ωy, ωz) when the yaw angle angle range detected by the yaw angle angle range detection unit is an angle range between +135° and +180°;
(ωx′, ωy′, ωz′)=(ωy, −ωx, ωz) when the yaw angle angle range detected by the yaw angle angle range detection unit is an angle range between −45° and −135°; and
(ωx′, ωy′, ωz′)=(−ωx, −ωy, ωz) when the yaw angle angle range detected by the yaw angle angle range detection unit is an angle range between −135° and −180°.

6. The autonomous navigation system according to claim 4, wherein:
the inertial sensor is configured to output angular velocities (ωx, ωy, ωz) around the three axes of X, Y, and Z in addition to the accelerations (ax, ay, az); and
the conversion unit is further configured to perform conversion of the angular velocities (ωx, ωy, ωz) into angular velocities (ωx′, ωy′, ωz′) as the conversion, and to perform conversion into the angular velocities (ωx′, ωy′, ωz′) by setting:
(ωx′, ωy′, ωz′)=(ωx, ωy, ωz) when the yaw angle angle range detected by the yaw angle angle range detection unit is an angle range between −45° and +45°;
(ωx′, ωy′, ωz′)=(−ωy, ωx, ωz) when the yaw angle angle range detected by the yaw angle angle range detection unit is an angle range between +45° and +135°;
(ωx′, ωy′, ωz′)=(−ωx, −ωy, ωz) when the yaw angle angle range detected by the yaw angle angle range detection unit is an angle range between +135° and +180°;
(ωx′, ωy′, ωz′)=(ωy, −ωx, ωz) when the yaw angle angle range detected by the yaw angle angle range detection unit is an angle range between −45° and −135°; and
(ωx′, ωy′, ωz′)=(−ωx, −ωy, ωz) when the yaw angle angle range detected by the yaw angle angle range detection unit is an angle range between −135° and −180°.

7. The autonomous navigation system according to claim 2, wherein:
the yaw angle angle range detection unit is configured to detect the yaw angle of the attachment angle of the inertial sensor with respect to the moving body; and
the autonomous navigation system includes an initial value setting unit configured to:
calculate a yaw angle of the virtual inertial sensor on the basis of the yaw angle and the yaw angle angle range detected by the yaw angle angle range detection unit; and
set the yaw angle in the Kalman filter as an initial value of a yaw angle of an attachment angle estimated by the Kalman filter.

8. The autonomous navigation system according to claim 7, wherein:
the yaw angle angle range detection unit is configured to detect a roll angle and a pitch angle of the attachment angle of the inertial sensor with respect to the moving body; and
the initial value setting unit is configured to calculate a pitch angle of the virtual inertial sensor on the basis of the roll angle, the pitch angle, and the yaw angle angle range detected by the yaw angle angle range detection unit, and to set the pitch angle in the Kalman filter as an initial value of a pitch angle of an attachment angle estimated by the Kalman filter.

9. The autonomous navigation system according to claim 3, wherein:
the yaw angle angle range detection unit is configured to detect a roll angle A1, a pitch angle A2, and a yaw angle A3 of the attachment angle of the inertial sensor with respect to the moving body; and
the autonomous navigation system includes an initial value setting unit configured to set an initial value SA2 of a pitch angle and an initial value SA3 of a yaw angle of an attachment angle estimated by the Kalman filter;
wherein the initial value setting unit is configured to calculates the initial value SA2 and the initial value SA3 of the yaw angle as:
SA2=A2
SA3=A3
when the yaw angle angle range detected by the yaw angle angle range detection unit is an angle range between −45° and +45°;
SA2=A1
SA3=A3−90°
when the yaw angle angle range detected by the yaw angle angle range detection unit is an angle range between +45° and +135°;
SA2=−A2
SA3=A3−180°
when the yaw angle angle range detected by the yaw angle angle range detection unit is an angle range between +135° and +180°;
SA2=−A1
SA3=A3+90°
when the yaw angle angle range detected by the yaw angle angle range detection unit is an angle range between −45° and −135°; and
SA2=−A2
SA3=A3+180°
when the yaw angle angle range detected by the yaw angle angle range detection unit is an angle range between −135° and −180°.
